(19) United States
(12) Patent Application Publication
(10) Pub. No.: US 2012/0001256 A1
(43) Pub. Date: Jan. 5, 2012

(54) SEMICONDUCTOR DEVICE

(75) Inventor: Kazuhiro NOJIMA, Tokyo (JP)

(73) Assignee: ELPIDA MEMORY, INC., Tokyo (JP)

(21) Appl. No.: 13/169,566

(22) Filed: Jun. 27, 2011

(30) Foreign Application Priority Data
Jul. 1, 2010 (JP) 2010-150838

(51) Int. Cl. H01L 29/78

(52) U.S. Cl. 257/329; 257/E29.264; 257/E29.262

(57) ABSTRACT

A semiconductor device includes: a first insulator pillar surrounding an active region; a second insulator pillar with a second side surface opposed in a y direction to a first side surface of the first insulator pillar on the active region side; an insulating film covering top surfaces of first and second insulator pillars; a second gate electrode electrically connected to the first gate electrode, covering at least the first and second side surfaces; and a gate contact plug in a contact hole and electrically connected to a top surface of the second gate electrode, the insulating film and the second gate electrode being exposed in a bottom of the contact hole. A distance between first and second side surfaces<a length of the gate contact plug in the y direction. The gate contact plug is electrically connected to the second gate electrodes between the first and second side surfaces.

### BACKGROUND OF THE INVENTION

1. Field of the Invention

The present invention relates to a semiconductor device, and more particularly to a semiconductor device that uses a vertical transistor.

2. Description of Related Art

Semiconductor devices, or memory devices in particular, have been reduced in chip size each year in terms of cost reduction. More and more DRAMs (dynamic random access memories) are adopting vertical transistors of 4F² structure as their cell transistors (for example, see United States Patent Application Publication No. 2009/0065856 A1). Peripheral circuits continue using transistors of conventional planar type because not as much reduction is needed as with cell transistors. Since a difference in structure between the cell and peripheral circuit transistors can greatly increase the number of processes, the use of vertical transistors even for peripheral circuit transistors has recently been under review.

The vertical transistor to be installed in a peripheral circuit is composed of two adjoining silicon pillars as described in the Publication No. 2009/0065856 A1. One of the silicon pillars is used as a channel. Impurity diffused layers are formed on top and bottom of the silicon pillar, and the side surface is covered with a gate electrode via a gate insulating film. The other silicon pillar is a dummy silicon pillar for extending the length of the gate electrode in the lateral direction. The extended portion is utilized to form a gate contact plug.

The processes up to the formation of the gate contact plug will be briefly described. Initially, the surface of a silicon substrate is patterned by using a hard mask (silicon nitride film) to form two silicon pillars. Next, the entire surface including the hard mask is covered with a silicon oxide film. The side surfaces of the respective silicon pillars are further covered with a sidewall nitride film, and in that state an impurity is implanted into the silicon substrate. The impurity implanted here constitutes the lower diffusion layer. After the completion of the implantation, the sidewall nitride film and the silicon oxide film are etched off in order.

Next, the side surfaces of the silicon pillars are thermally oxidized to form a gate insulating film. Conductive material is further deposited and etched back to form a gate electrode on the side surfaces of the silicon pillars. Next, the entire article is covered with a silicon oxide film, and the surface is polished by chemical mechanical polishing (CMP) until the top surface of the hard mask is exposed. With the top surface of the hard mask exposed, the hard mask is removed from only where it is formed on the top surface of the channel silicon pillar. A sidewall nitride film is formed in the opening that is made by the removal, and an impurity is implanted into the upper part of the channel silicon pillar. The impurity implanted here constitutes the upper diffusion layer. Subsequently, the entire surface is covered with a silicon oxide film again. The silicon oxide film is etched to form contact holes that expose the top surfaces of the lower diffusion layer, the upper diffusion layer, and the gate electrode, respectively. Conductive material is then filled into the contact holes to form three contact plugs that are in connection with the lower diffusion layer, the upper diffusion layer, and the gate electrode, respectively.

Of the three contact plugs thus formed, the one in connection with the gate electrode is the gate contact plug mentioned above. The gate contact plug is connected to the gate electrode in part of the periphery of the dummy silicon pillar.

### SUMMARY

The vertical transistor formed as described above, however, has a problem that it is difficult to control the depth of the contact hole for forming the gate contact plug and it is not possible to sufficiently secure an electrical connection between the gate contact plug and the gate electrode. Details will be given below.

To make the contact hole, it is needed to etch the silicon oxide film and avoid etching the hard mask (silicon nitride film) on top of the dummy silicon pillar. High selectivity etching is used for that purpose, whereas such etching has the characteristic that the etching rate of the silicon oxide film varies with the materials that appear in the bottom of the contact hole. Specifically, the higher the proportion of the silicon nitride film to the bottom area of the contact hole, the lower the etching rate of the silicon oxide film.

The contact hole for forming the gate contact plug is located in the periphery of the dummy silicon pillar, and the hard mask appears in the bottom of the contact hole as the etching proceeds. Since the hard mask is a silicon nitride film, the etching rate of the silicon oxide film decreases with the increasing proportion of the hard mask to the bottom area of the contact hole.

The position to make the contact hole can be misaligned in the horizontal direction. The misalignment, if occurs, changes the proportion of the hard mask to the bottom area of the contact hole. The change results in a change in the etching rate of the silicon oxide film. Since the occurrence or magnitude of the misalignment is unpredictable, it is not possible to predict the change in etching rate, which makes appropriate depth control on the contact hole difficult. A semiconductor device that allows appropriate depth control on the contact hole for forming the gate contact plug is therefore desired.

In one embodiment, there is provided a semiconductor device comprising: a silicon substrate; a first silicon pillar that is formed in an active region on a surface of the silicon substrate; an upper diffusion layer and a lower diffusion layer that are formed on top and bottom of the first silicon pillar, respectively; a first gate electrode that covers a side surface of the first silicon pillar via a gate insulating film; a first insulator pillar that surrounds the active region; a second insulator pillar that has a second side surface which is opposed in a first direction to a first side surface of the first insulator pillar on the active region side; an insulating film that covers top surfaces of the first and second insulator pillars; a second gate electrode that is electrically connected to the first gate electrode and covers at least the first and second side surfaces; and a gate contact plug that is arranged in a contact hole and is electrically connected to a top surface of the second gate electrode, the insulating film and the second gate electrode being exposed in a bottom of the contact hole, a distance between the first and second side surfaces being smaller than a length of the gate contact plug in the first direction, the gate contact plug being electrically connected to the second gate electrode in an area between the first and second side surfaces.

In another embodiment, there is provided a semiconductor device comprising: a silicon substrate; a first silicon pillar that is formed in an active region on a surface of the silicon substrate; an upper diffusion layer and a lower diffusion layer that are formed on top and bottom of the first silicon pillar, respectively; a first gate electrode that covers a side surface of the first silicon pillar via a gate insulating film; a dummy pillar that has first and second side surfaces opposed to each other in a first direction; an insulating film that covers a top surface of the dummy pillar; a second gate electrode that is electrically connected to the first gate electrode and covers at least the first and second side surfaces; and a gate contact plug that is arranged in a contact hole and is electrically connected to a top surface of the second gate electrode, the insulating film and the second gate electrode being exposed in a bottom of the contact hole, a distance between the first and second side surfaces being smaller than a length of the gate contact plug in the first direction, the gate contact plug being electrically connected to the second gate electrode in an area between the first and second side surfaces.

According to the present invention, it is possible to suppress a change in the proportion of the silicon nitride film to the bottom area of the contact hole, the change resulting from misalignment that occurs when the contact hole for forming the gate contact plug is formed. As compared to the background art, it is therefore possible to appropriately control the depth of the contact hole for forming the gate contact plug.

### BRIEF DESCRIPTION OF THE DRAWINGS

The above features and advantages of the present invention will be more apparent from the following description of certain preferred embodiments taken in conjunction with the accompanying drawings, in which:

FIGS. 1A and 1B are plan views of a semiconductor device according to a first embodiment of the present invention;

FIGS. 2A and 2B are sectional views of the semiconductor device according to the first embodiment of the present invention;

FIG. 3A is a schematic diagram showing the state where the etching of the gate contact hole according to the first embodiment of the present invention reaches near the surface of the insulating film, the hard mask;

FIG. 3B is a schematic diagram showing the state where the etching of the gate contact hole according to the background art of the present invention similarly reaches near the surface of a silicon nitride film, the hard mask;

FIG. 4 is a plan view of a semiconductor device according to a second embodiment of the present invention;

FIG. 5 is a sectional view of the semiconductor device according to the second embodiment of the present invention;

FIG. 6 is a plan view of a semiconductor device according to a third embodiment of the present invention;

FIGS. 7A and 7B are plan views of a semiconductor device according to a fourth embodiment of the present invention; and

FIGS. 8A and 8B are sectional views of the semiconductor device according to the fourth embodiment of the present invention.

### DETAILED DESCRIPTION OF THE EMBODIMENTS

Hereinafter, preferred embodiments of the present invention will be described in detail with reference to the accompanying drawings.

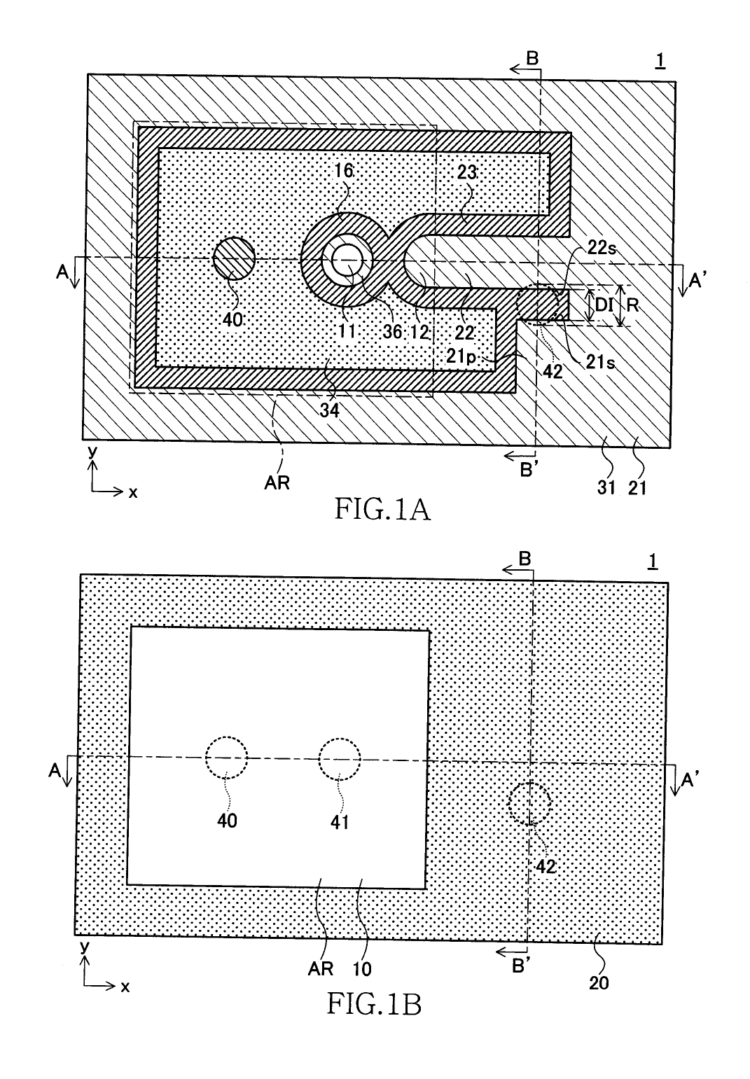

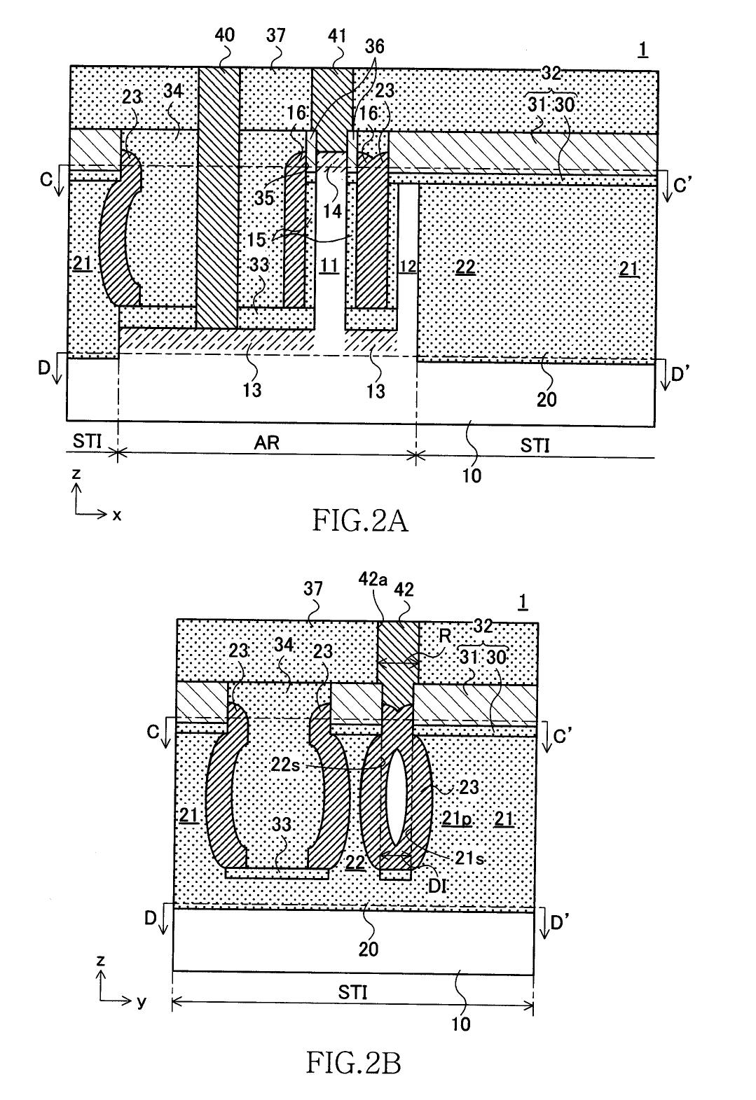

FIGS. 1A and 1B are plan views of a semiconductor device 1 according to a first embodiment of the present invention. FIG. 2A is a sectional view of the semiconductor device 1 corresponding to the section that is taken along the line A-A′ shown in FIGS. 1A and 1B. FIG. 2B is a sectional view of the semiconductor device 1 corresponding to the section that is taken along the line B-B′ shown in FIGS. 1A and 1B. The plan view of FIG. 1A corresponds to the plane along the line C-C′ shown in FIGS. 2A and 2B. The plan view of FIG. 1B corresponds to the plane along the line D-D′ shown in FIGS. 2A and 2B.

As shown in FIGS. 1A, 1B, 2A, and 2B, the semiconductor device 1 includes a silicon substrate 10, on the surface of which an active region AR and an element isolation region STI are arranged. A silicon oxide film 20 is buried in the element isolation region STI, whereby the active region AR is insulated from adjoining other active regions AR (not shown).

The active region AR has first and second silicon pillars 11 and 12. The first and second silicon pillars 11 and 12 both are pillars of columnar shape. The first silicon pillar 11 is arranged separate from other pillars. The second silicon pillar 12 is connected to the end portion of a second insulator pillar 22 to be described later (the end of a peninsular portion).

The element isolation region STI includes first and second insulator pillars 21 and 22. The first insulator pillar 21 is a pillar of rectangular cylindrical shape which is arranged to surround the active region AR. The second insulator pillar 22 is a pillar of columnar shape. The second insulator pillar 22 has a side surface 22s, which is opposed in the shown y direction to a side surface 21s (first side surface) of the first insulator pillar 21 on the active region AR side. Hereinafter, the distance between the side surfaces 21s and 22s (the distance in the y direction) will be represented by DI.

The second insulator pillar 22 is arranged in the area surrounded by the first insulator pillar 21, and is formed integrally with the first insulator pillar 21 and the second silicon pillar 12. In other words, the second insulator pillar 22 has a peninsular shape protruding from the first insulator pillar 21 toward the active region AR, and the second silicon pillar 12 is formed on its extremity. The side surface 22s refers to a side surface of the base of the peninsular shape.

The first insulator pillar 21 has a portion 21p which protrudes toward the active region AR. The side surface 21s refers to the side surface of the portion 21p.

The portion 21p of the first insulator pillar 21, the second insulator pillar 22, and the second silicon pillar 12 constitute a dummy pillar for extending the length of the gate electrode in the horizontal direction. The side surfaces 21s and 22s are the two of the side surfaces of the dummy pillar that are opposed to each other in the y direction.

The steps of forming the first and second silicon pillars 11 and 12 and the first and second insulator pillars 21 and 22 will be described. Initially, a substrate protective film 30 made of a silicon oxide film is formed over the entire surface of the silicon surface 10 with the silicon oxide film 20 buried therein. An insulating film 31 made of a silicon nitride film is further formed thereon. Though not limited in particular, the substrate protective film 30 and the insulating film 31 can be formed by chemical vapor deposition (CVD). The substrate protective film 30 preferably has a thickness of approximately 5 nm, and the insulating film 31 a thickness of approximately 120 nm. Hereinafter, the layered film of the substrate protective film 30 and the insulating film 31 will sometimes be referred to collectively as a hard mask 32.

The hard mask 32 formed is patterned so that the hard mask 32 is removed except from the areas for forming the pillars. Using such a patterned hard mask 32, the exposed surfaces of the silicon substrate 10 and the silicon oxide film 20 are etched down by dry etching. This forms the first and second silicon pillars 11 and 12 made of silicon and the first and second insulator pillars 21 and 22 made of a silicon oxide film.

As shown in FIG. 2B, both the side surfaces 21s and 22s are largely recessed. The reason is that there is a need to overetch the silicon oxide film in a subsequent step (the step after the formation of a lower diffusion layer 13 and before the formation of a gate insulating film). Details will be given later.

The semiconductor device 1 further includes the lower diffusion layer 13, an upper diffusion layer 14, a gate insulating film 15, a first gate electrode 16, and a second gate electrode 23. The upper and lower diffusion layers 14 and 13 are formed on top and bottom of the first silicon pillar 11, respectively. The first gate electrode 16 covers the side surface of the first silicon pillar 11 via the gate insulating film 15. The second gate electrode 23 is electrically connected to the first gate electrode 16 and covers at least the side surfaces 21s and 22s.

The lower diffusion layer 13 is an impurity diffused layer that is formed by implanting an impurity into the surface (bottom) of the active region AR except where the first and second silicon pillars 11 and 12 are formed.

The steps of forming the lower diffusion layer 13 will be described. After the formation of the pillars, a sidewall insulating film (not shown) is initially formed on the side surfaces of the pillars. The sidewall insulating film is formed by protecting the entire surface of the silicon substrate 10 including the hard mask 32 with a thermally-oxidized film (not shown), forming a silicon nitride film thereon, and etching back the silicon nitride film. In consequence, the side surfaces of the pillars are covered with the sidewall insulating film.

Next, the bottom of the active region AR is thermally oxidized to form a silicon oxide film 33. Here, the silicon oxide film 33 is also formed at the bottom of the element isolation region STI. As can be seen from a comparison of FIGS. 2A and 2B, the portion formed in the element isolation region STI has a thickness smaller than that of the portion that is formed at the bottom of the active region AR. The reason is that the element isolation region STI is bottomed with the silicon oxide film 20 which is already oxidized. The side surfaces of the pillars are not thermally oxidized because of the presence of the sidewall insulating film.

Next, impurity ions having a conductivity type opposite to that of the impurity of the silicon substrate 10 are implanted through the silicon oxide film 33 formed. The lower diffusion layer 13 is formed by the steps so far. After the formation of the lower diffusion layer 13, the sidewall insulating film on the side surfaces of the pillars and the thermally-oxidized film are removed by wet etching. Here, overetching is performed so as to leave no silicon oxide film on the side surfaces of the pillars. Consequently, the side surfaces of the first and second insulator pillars 21 and 22 are largely recessed as shown in FIG. 2B and other figures.

The gate insulating film 15 is a thermally-oxidized film that is formed by thermally oxidizing the side surface of the first silicon pillar 11 after the completion of the wet etching. In the thermal oxidation, the side surface of the second silicon pillar 12 is also thermally oxidized at the same time, whereby the gate insulating film 15 is formed even on the side surface of the second silicon pillar 12 as shown in FIG. 2A.

The first gate electrode 16 is a conductive film that covers the side surface of the first silicon pillar 11 via the gate insulating film 15. The second gate electrode 23 is a conductive film which covers the side surfaces of the area that is defined by the second silicon pillar 12 and the first and second insulator pillars 21 and 22 (side surfaces including the side surfaces 21s and 22s). Such electrodes are simultaneously formed by forming a polysilicon film (conductive film) having a thickness of approximately 30 nm over the entire surface of the silicon substrate 10 by CVD and etching back the polysilicon film by anisotropic dry etching. Aside from the polysilicon film, the first and second gate electrodes 16 and 23 may be made of metal material such as tungsten.

The first gate electrode 16 and the second gate electrode 23 are electrically connected to each other. Such a connection is achieved by making the distance between the first silicon pillar 11 and the second silicon pillar 12 smaller than twice the thickness of the first and second gate electrodes 16 and 23.

The upper diffusion layer 14 is an impurity diffused layer that is formed by implanting an impurity into the upper end of the first silicon pillar 11.

The steps of forming the upper diffusion layer 14 will be described. After the formation of the first and second gate electrodes 16 and 23, a silicon oxide film 34 is formed over the entire surface of the silicon substrate 10 by a high density plasma (HDP) method. The surface is polished and flattened by CMP. Here, the hard mask 32 plays the role of a stopper, which allows reliable control on the thickness of the silicon oxide film 34. In consequence, the areas between the pillars are filled with the silicon oxide film 34.

Next, approximately 5 nm of silicon oxide film (mask oxide film; not shown) is formed over the entire surface of the silicon substrate 10 by CVD. The mask oxide film is then patterned so that the hard mask 32 lying on the first silicon pillar 11 is exposed and the hard mask 32 lying on the other pillars is not. Subsequently, the insulating film 31 in the exposed hard mask 32 is removed by dry etching or wet etching. This forms a through hole 35 above the first silicon pillar 11. A low concentration of impurity ions having a conductivity type opposite to that of the impurity of the silicon substrate 10 are shallowly implanted into the bottom of the through hole 35 via the substrate protective film 30. Consequently, a lightly doped drain (LDD) region (not shown) is formed at the top end of the first silicon pillar 11.

Next, a sidewall insulating film 36 is formed on the inner wall surface of the through hole 35. The sidewall insulating film 36 is formed by forming a silicon nitride film over the entire surface of the silicon substrate 10, followed by etchback. Though not limited in particular, it is preferred that the sidewall insulating film 36 have a thickness of approximately 10 nm. The substrate protective film 30 at the bottom of the through hole 35 is then removed by dilute hydrofluoric acid before silicon is epitaxially grown in the through hole 35 selectively. A high concentration of impurity ions having the conductivity type opposite to that of the impurity of the silicon substrate 10 are implanted into the silicon epitaxial layer formed (not shown). The upper diffusion layer 14 is formed by such steps.

With the structure described above, a MOS transistor channel is formed in the first silicon pillar 11. The lower diffusion layer 13, the upper diffusion layer 14, and the first and second gate electrodes 16 and 23 function as either one of the source and drain of the MOS transistor, the other of the source and drain, and the gate electrode, respectively. Such a MOS transistor can be suitably used for a peripheral circuit of DRAM, for example.

The semiconductor device 1 also includes a lower diffusion layer contact plug 40, an upper diffusion layer contact plug 41, and a gate contact plug 42 which are intended to connect the lower diffusion layer 13, the upper diffusion layer 14, and the second gate electrode 23 to the wiring of an upper layer, respectively.

The steps of forming the contact plugs will be described. After the formation of the upper diffusion layer 14, a silicon oxide film is deposited on the entire surface of the silicon substrate 10. The surface is flattened by CMP to form an interlayer insulating film 37. Next, a resist is applied to the surface of the interlayer insulating film 37. The interlayer insulating film 37 is etched by photolithography, whereby contact holes are formed in positions to form the respective contact plugs. The contact holes are filled with titanium nitride and tungsten in this order, thereby contact plugs made of a layered film of titanium nitride and tungsten are formed. It should be noted that the three contact holes and the three contact plugs are not simultaneously formed but one by one. The reason is that the contact holes need respective different depths.

The gate contact plug 42 is electrically connected to the second gate electrode 23 in the area between the side surfaces 21s and 22s mentioned above. For that purpose, the contact hole for forming the gate contact plug 42 (gate contact hole 42a) is also formed in the foregoing area between the side surfaces 21s and 22s. The length (diameter R) of the gate contact hole 42a in the y direction is set to be greater than the distance DI between the side surfaces 21s and 22s. More specifically, the length is set so that the silicon nitride film 31 is exposed at both sides of the bottom of the gate contact hole 42a even if the gate contact hole 42a is formed with misalignment.

The foregoing setting of the length of the gate contact hole 42a in the y direction can suppress a change in the proportion of the silicon nitride film to the bottom area of the gate contact hole 42a, the change resulting from the misalignment that occurs when the gate contact hole 42a is formed. This makes it possible to appropriately control the depth of the gate contact hole 42a as compared to the background art. Detailed description thereof will be given below with reference to the drawings.

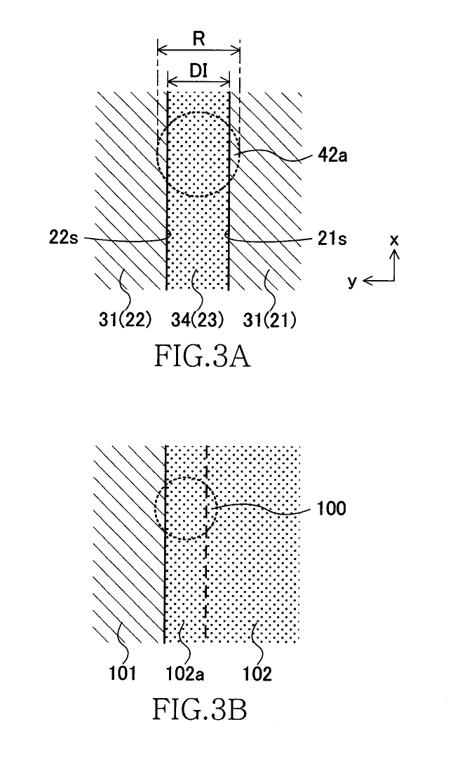

FIG. 3A is a schematic diagram showing the state where the etching of the gate contact hole 42a according to the present embodiment reaches near the surface of the insulating film 31. FIG. 3B is a schematic diagram showing the state where the etching of the gate contact hole according to the background art similarly reaches near the surface of a silicon nitride film, the hard mask. In FIG. 3B, the areas designated by the reference numbers 100, 101, and 102 represent a gate contact hole, the silicon nitride film or hard mask, and a silicon oxide film, respectively. A gate electrode is embedded under the area designated by the reference number 102a.

Initially, referring to FIG. 3A, the insulating film 31 is exposed at both sides of the bottom of the gate contact hole 42a in the y direction. Consequently, even if the gate contact hole 42a is misaligned in the y direction, the proportion of the silicon nitride film to the bottom area of the gate contact hole 42a does not vary much. In contrast, referring to FIG. 3B, the silicon nitride film 101 is exposed at only one side of the bottom of the gate contact hole 100. If the gate contact hole 100 is misaligned in the horizontal direction in the diagram, then the proportion of the silicon nitride film 101 to the bottom area of the gate contact hole 100 varies greatly.

As described above, according to the background art, the misalignment of the gate contact hole 100 greatly affects the proportion of the silicon nitride film 101 to the bottom area of the gate contract hole 100. In contrast, in the semiconductor device 1, the misalignment of the gate contact hole 42a, if any, will not much affect the proportion of the insulating film 31 to the bottom area of the gate contact hole 42a. In the semiconductor device 1, it is therefore possible to appropriately control the depth of the gate contact hole 42a as compared to the background art.

As has been described above, according to the semiconductor device 1 of the present embodiment, it is possible to appropriately control the depth of the gate contact hole as compared to the background art.

According to the semiconductor device 1, the dummy pillar lying near the portion where the second gate electrode 23 makes contact with the gate contact plug 42 is made of a silicon oxide film pillar. This prevents the occurrence of parasitic capacitance between the dummy pillar and the gate contact plug 42.

The dummy pillar made of a silicon oxide film pillar is largely recessed in the side surface in the course of processing as described above. The semiconductor device 1 can prevent collapse of the dummy pillar and disappearance of the hard mask 32 due to the collapsing even in the presence of the recess. Specific description will be given below.

First, the second insulator pillar 22 is formed integrally with the first silicon oxide film pillar 21 which has a large area and the second silicon pillar 12 whose side surface will not be recessed in the course of processing. The second insulator pillar 22 is thus supported by such pillars and prevented from collapsing even if thinned. This also prevents the disappearance of the hard mask 32 which is formed on the second insulator pillar 22.

Secondly, the portion 21p is apart of the first silicon oxide film pillar 21 which has a large area. The portion 21p is thus supported by the other parts of the first silicon oxide film pillar 21 even if largely recessed in the side surface. This prevents collapsing and prevents the disappearance of the hard mask 32 formed on the top.

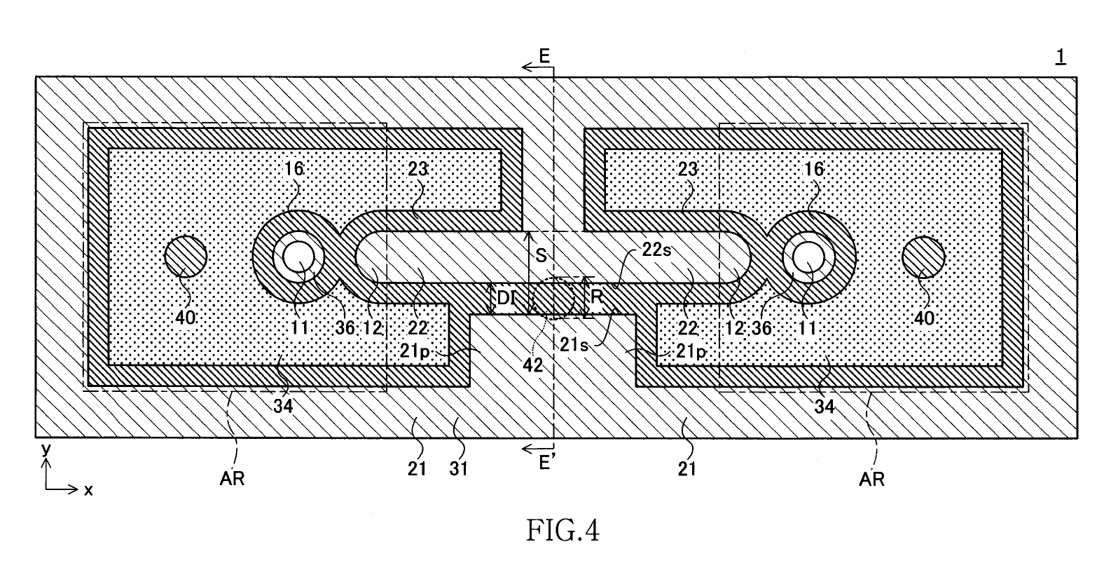

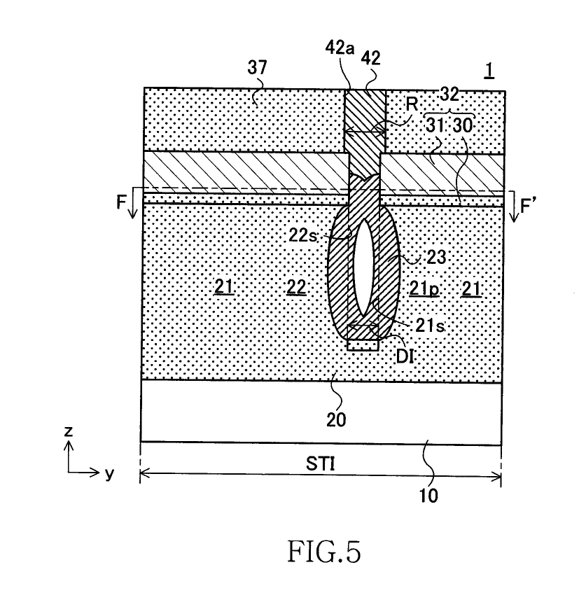

FIG. 4 is a plan view of a semiconductor device 1 according to a second embodiment of the present invention. FIG. 5 is a sectional view of the semiconductor device 1 corresponding to the section that is taken along the line E-E′ shown in FIG. 4. The plan view of FIG. 4 corresponds to the plane along the line F-F′ shown in FIG. 5. In FIGS. 4 and 5, the same components as in the first embodiment are designated by like reference numbers.

In the present embodiment, the side surfaces 21s and 22s and the gate contact plug 42 described in the first embodiment are shared between two adjoining active regions AR. The second insulator pillar 22 and the portion 21p of the first insulator pillar 21 are also shared between the two adjoining active regions AR. Hereinafter, detailed description will be given with a focus on differences from the first embodiment.

As shown in FIG. 4, the active regions AR have first and second silicon pillars 11 and 12 each. The pillars have the same shape as in the first embodiment.

The element isolation region STI includes first and second insulator pillars 21 and 22. The first insulator pillar 21 is configured so that two insulator pillars of rectangular cylindrical shape, surrounding the respective active regions AR, are united with each other in the area between the two active regions AR. It should be noted that the first insulator pillar 21 has a gap S shown in FIG. 4 in the area between the two active regions AR.

The second insulator pillar 22 extends from the side of one of the active regions AR to the side of the other active regions AR through the foregoing gap S. The second insulator pillar 22 is connected to the second silicon pillars 11 formed in the respective active regions AR at both longitudinal ends. The second insulator pillar 22 is connected to the first insulator pillar 21 at one of two side surfaces on the respective lateral ends. The side surface 22s which is opposed to the side surface 21s is one of the two longitudinal side surfaces, the one not being connected to the first insulator pillar 21.

The first insulator pillar 21 has ends that face the gap S. One of the ends that is not connected to the second insulator pillar 22 constitutes the portion 21p which protrudes toward the active regions AR. The side surface 21s of the portion 21p is arranged in parallel with the side surface 22s, and is opposed to the side surface 22s in the y direction.

As in the first embodiment, the second gate electrode 23 covers the side surfaces of the areas that are defined by the second silicon pillars 12 and the first and second insulator pillars 21 and 22 (side surfaces including the side surfaces 21s and 22s). The two second gate electrodes 23 corresponding to the respective active regions AR are formed integrally with each other in the gap S.

The gate contact plug 42 is electrically connected to the second gate electrode 23 in the area between the side surfaces 21s and 22s. The gate contact hole 42a for forming the gate contact plug 42 has a length (diameter R) greater than the distance DI between the side surfaces 21s and 22s in the y direction. Consequently, like the first embodiment, the second embodiment provides the effect that it is possible to appropriately control the depth of the gate contact hole as compared to the background art.

As has been described above, according to the semiconductor device 1 of the present embodiment, it is possible to appropriately control the depth of the gate contact hole as compared to the background art when the gate contact plug is formed common to two adjoining active regions AR.

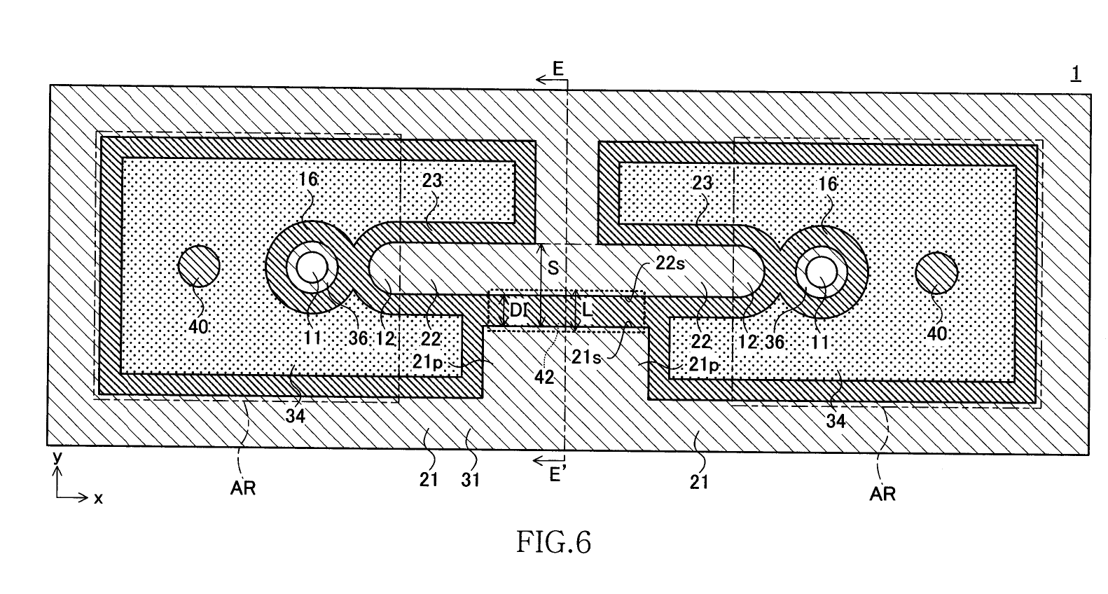

FIG. 6 is a plan view of a semiconductor device 1 according to a third embodiment of the present invention. In FIG. 6, the same components as in the first and second embodiments are designated by like reference numbers.

As shown in FIG. 6, the present embodiment differs from the second embodiment in the planar shape of the gate contact plug 42. Specifically, the gate contact plug 42 has a rectangular planar shape as shown in FIG. 6.

The length of the gate contact plug 42 in the direction in which the side surfaces 21s and 22s are opposed to each other (y direction) is greater than the distance DI between the side surfaces 21s and 22s. Like the first and second embodiments, the third embodiment therefore provides the effect that it is possible to appropriately control the depth of the gate contact hole as compared to the background art.

In addition, according to the present embodiment, the proportion of the silicon nitride film to the bottom area of the gate contact hole will not vary at all even if the gate contact hole is moved in the y direction, as long as the amount of movement falls within a range such that the insulating film 31 is exposed at both sides of the bottom of the gate contact hole. This allows more precise control on the depth of the gate contact hole.

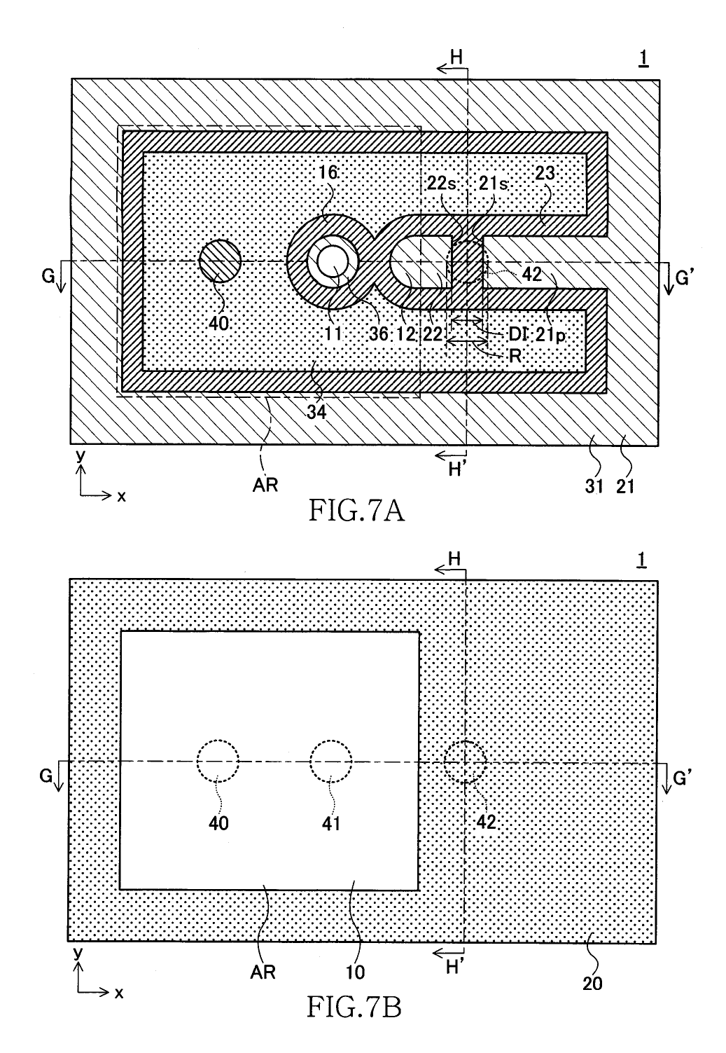

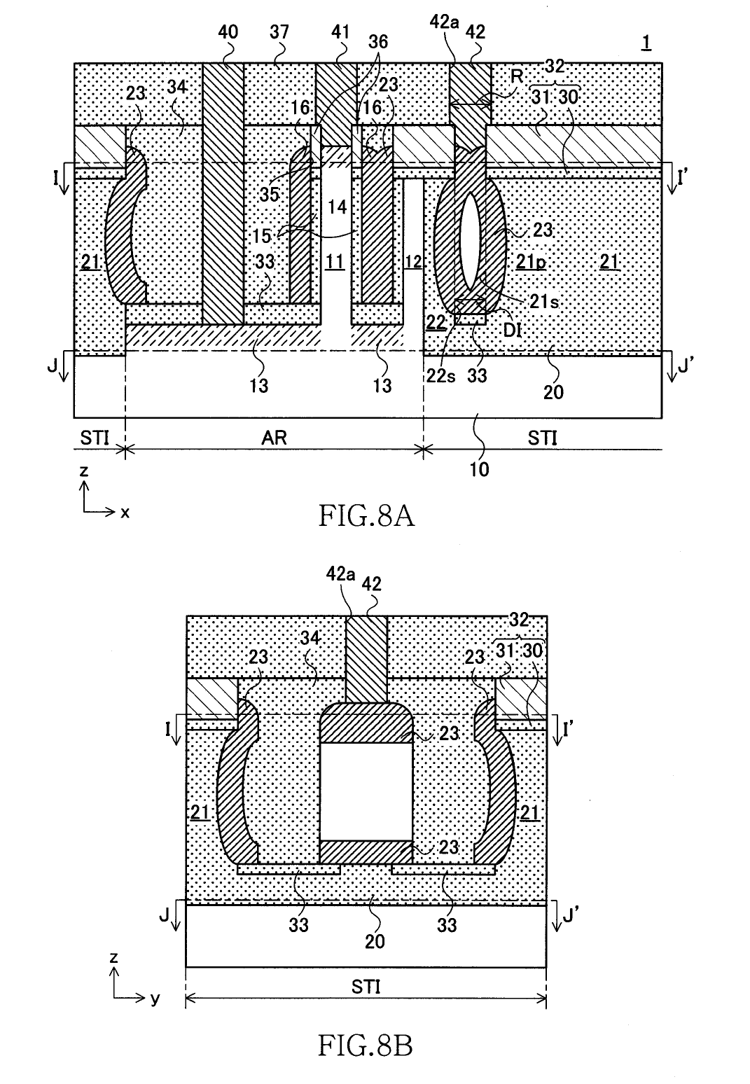

FIGS. 7A and 7B are plan views of a semiconductor device 1 according to a fourth embodiment of the present invention. FIG. 8A is a sectional view of the semiconductor device 1 corresponding to the section that is taken along the line G-G′ shown in FIGS. 7A and 7B. FIG. 8B is a sectional view of the semiconductor device 1 corresponding to the section that is taken along the line H-H′ shown in FIGS. 7A and 7B. The plan view of FIG. 7A corresponds to the plane along the line I-I′ shown in FIGS. 8A and 8B. The plan view of FIG. 7B corresponds to the plane along the line J-J′ shown in FIGS. 8A and 8B. In FIGS. 7 and 8, the same components as in the first to third embodiments are designated by like reference numbers.

The present embodiment differs from the first embodiment in the planar shape of the first and second insulator pillars 21 and 22. Hereinafter, detailed description will be given with a focus on differences from the first embodiment.

In the present embodiment, the portion 21p of the first insulator pillar 21 has a peninsular shape protruding from the first insulator pillar 21 toward the active region AR. The side surface 21s to be opposed to the side surface 22s refers to the side surface of the top part of the peninsular shape.

The second insulator pillar 22 is the same as that of the first embodiment in being a pillar of columnar shape and being formed integrally with the second silicon pillar 12. However, the second insulator pillar 22 is formed separate from the first insulator pillar 21. The side surface 22s refers to the one closer to the first insulator pillar 21 (on the side opposite from the active region AR) and is opposed to the side surface 21s in the x direction. The distance DI between the side surfaces 21s and 22s is thus the distance in the x direction. The length (diameter R) of the gate contact hole 42a in the x direction is set to be longer than the distance DI between the side surfaces 21s and 22s.

According to the semiconductor device 1 of the present embodiment, the proportion of the insulating film 31 to the bottom area of the gate contact hole 42a will not vary much even if the gate contact hole 42a is misaligned in the x direction. This makes it possible to appropriately control the depth of the gate contact hole 42a as compared to the background art.

In addition, the second insulator pillar 22 is formed integrally with the second silicon pillar 12 whose side surface will not be recessed in the course of processing. The second insulator pillar 22 is thus supported by the second silicon pillar 12 even if thinned in the course of processing. This prevents the second insulator pillar 22 from collapsing. Similarly, the hard mask 32 lying on the second insulator pillar 22 is formed integrally with the hard mask 32 that is formed on the second silicon pillar 12, and is thus prevented from disappearing.

It is apparent that the present invention is not limited to the above embodiments, but may be modified and changed without departing from the scope and spirit of the invention.

What is claimed is:

1. A semiconductor device comprising:
a silicon substrate having an active region;
a first silicon pillar that is formed in the active region;
an upper diffusion layer and a lower diffusion layer that are formed on upper and lower portions of the first silicon pillar, respectively;
a first gate electrode that covers a side surface of the first silicon pillar via a gate insulating film;
a first insulator pillar having a first side surface that surrounds the active region;
a second insulator pillar that has a second side surface opposed to the first side surface in a first direction;
an insulating film that covers top surfaces of the first and second insulator pillars;
a second gate electrode that is electrically connected to the first gate electrode and covers at least the first and second side surfaces; and
a gate contact plug that is arranged in a contact hole exposing apart of the insulating film and apart of the second gate electrode, thereby the gate contact plug is electrically connected to the second gate electrode in an area between the first and second side surfaces,
wherein a distance between the first and second side surfaces in the first direction is smaller than a diameter of the gate contact plug in the first direction.

2. The semiconductor device as claimed in claim 1, wherein the second insulator pillar is formed integrally with the first insulator pillar.

3. The semiconductor device as claimed in claim 1, wherein the second insulator pillar is formed separate from the first insulator pillar.

4. The semiconductor device as claimed in claim 2, further comprising a second silicon pillar that is arranged in the active region,
wherein the second insulator pillar is formed integrally with the second silicon pillar.

5. The semiconductor device as claimed in claim 3, further comprising a second silicon pillar that is arranged in the active region,
wherein the second insulator pillar is formed integrally with the second silicon pillar.

6. The semiconductor device as claimed in claim 1, wherein
the insulating film comprises a silicon nitride, and
the first and second insulator pillars both comprise a silicon oxide.

7. The semiconductor device as claimed in claim 1, wherein
the active region includes first and second active regions close to each other,
the first silicon pillar is formed in each of the first and second active regions, and
the first and second side surfaces and the gate contact plug are formed common to the first and second active regions.

8. The semiconductor device as claimed in claim 1, wherein a length of the gate contact plug in a second direction orthogonal to the first direction is greater than that of the gate contact plug in the first direction.

9. A semiconductor device comprising:
a silicon substrate having an active region;
a first silicon pillar that is formed in the active region;
an upper diffusion layer and a lower diffusion layer that are formed on upper and lower portions of the first silicon pillar, respectively;
a first gate electrode that covers a side surface of the first silicon pillar via a gate insulating film;
a dummy pillar that has first and second side surfaces opposed to each other in a first direction;
an insulating film that covers atop surface of the dummy pillar;
a second gate electrode that is electrically connected to the first gate electrode and covers at least the first and second side surfaces; and
a gate contact plug that is arranged in a contact hole exposing apart of the insulating film and apart of the second gate electrode, thereby the gate contact plug is electrically connected to the second gate electrode in an area between the first and second side surfaces,
wherein a distance between the first and second side surfaces in the first direction is smaller than a diameter of the gate contact plug in the first direction.

10. The semiconductor device as claimed in claim 9, wherein
the insulating film comprises a silicon nitride, and
at least a part of the dummy pillar comprises a silicon oxide.
